(19) United States
(12) Patent Application Publication
(10) Pub. No.: US 2012/0256297 A1
(43) Pub. Date: Oct. 11, 2012

(54) METHOD FOR PRODUCING NITRIDE COMPOUND SEMICONDUCTOR SUBSTRATE, AND NITRIDE COMPOUND SEMICONDUCTOR FREE-STANDING SUBSTRATE

(76) Inventors: Satoru Morioka, Toda-shi (JP); Misao Takakusaki, Toda-shi (JP); Makoto Mikami, Toda-shi (JP); Takayuki Shimizu, Toda-shi (JP)

(21) Appl. No.: 13/515,861

(22) PCT Filed: Jan. 31, 2011
(86) PCT No.: PCT/JP2011/051855

§ 371 Date: Jun. 14, 2012

(30) Foreign Application Priority Data
Feb. 1, 2010 (JP) 2010-019900

(51) Int. Cl. H01L 29/20; H01L 21/20

(52) U.S. Cl. 257/615; 438/478; 257/E29.089; 257/E21.09

(57) ABSTRACT

Disclosed is a technique capable of preventing occurrence of warping in a nitride compound semiconductor layer, and by which a nitride compound semiconductor layer having small variations in the in-plane off angle can be grown with good reproducibility. Specifically disclosed is a method for producing a nitride compound semiconductor substrate using an HVPE process, wherein a low-temperature protective layer is formed on a rare earth perovskite substrate at a first growth temperature (a first step), and a thick layer composed of a nitride compound semiconductor is formed on the low-temperature protective layer at a second growth temperature that is higher than the first growth temperature (a second step). In the first step, the supply amounts of HCl and NH₃ are controlled so that the supply ratio of HCl to NH₃, namely the supply ratio III/V is 0.016-0.13, and the low-temperature protective layer has a film thickness of 50-90 nm.

### TECHNICAL FIELD

The present invention relates to a method of manufacturing a nitride-based compound semiconductor substrate using HVPE method and a nitride-based compound semiconductor free-standing substrate, and specifically relates to conditions for growing a low-temperature protecting layer.

### BACKGROUND ART

In a semiconductor device conventionally known (for example, an electronic or optical device), a nitride-based compound semiconductor such as GaN (hereinafter, referred to as a GaN-based semiconductor) is epitaxially grown on a substrate. Most of such semiconductor devices include substrates made of sapphire, SiC, or the like. However, these substrate materials have large lattice mismatch with GaN-based semiconductors. Accordingly, if the GaN-based semiconductors are epitaxially grown on the substrates made of the aforementioned materials, crystal defects due to distortion occur. The crystal defects caused in the epitaxial layers will degrade the characteristics of the semiconductor devices. Therefore, various growing methods have been tried to solve the above problems due to lattice mismatch.

Patent Literature 1,for example, proposes use of an NdGaO₃substrate (hereinafter, referred to as an NGO substrate) having a pseudo lattice constant close to those of GaN-based semiconductors. Specifically, Patent Literature 1 discloses a technique for growing a GaN thick film on an NGO substrate by hydride vapor phase epitaxy (HVPE) to produce a GaN free-standing substrate (a substrate composed of only GaN). The length of the a-axis of NGO is substantially equal to the lattice constant of GaN in the [11-20] direction in the (011) plane of the NGO substrate. Accordingly, the disclosed technique can solve the aforementioned problems due to lattice mismatch. Using a GaN free-standing substrate as a substrate for a semiconductor device can improve the characteristics of the device.

The GaN thick film layer is generally grown at a growth temperature of around 1000° C. However, when the NGO substrate is exposed to raw material gas at a high temperature of around 1000° C., the NGO substrate changes in nature, and the GaN thick film layer deteriorates in crystalline quality. Accordingly, there is a proposition of a technique to protect the NGO substrate by growing a GaN thin film layer referred to as a low-temperature protecting layer on the NGO substrate at around 600° C. before the GaN thick film layer is grown (for example, Patent Literatures 1 and 2).

### PRIOR ART LITERATURES

### Patent Literature

Patent Literature 1: Japanese Patent Laid-open Publication No. 2003-257854

Patent Literature 2: Japanese Patent Laid-open Publication No. 2000-4045

### DISCLOSURE OF THE INVENTION

### Problems to be Solved by the Invention

However, as the growth temperature is lowered to room temperature after the GaN thick film layer is grown at 1000° C., stress due to the difference in thermal expansion coefficient between GaN and NGO is applied to the GaN thick film layer. The GaN thick film layer is then warped and includes large in-plane variation of off-angle. If the warped GaN thick film layer is separated from the NGO substrate and a GaN free-standing substrate is cut out of the crystal of the GaN thick film, the GaN free-standing substrate includes large in-plane variation of off-angle. If the GaN free-standing substrate includes large in-plane variation of off-angle, semiconductor devices using such a GaN free-standing substrate could not provide desired characteristics (wavelength of light emitted from light emitting devices, for example).

An object of the present invention is to provide a method of manufacturing a nitride-based compound semiconductor substrate which is capable of reproducibly growing a nitride-based compound semiconductor substrate with small in-plane variation of off-angles while preventing the nitride-based compound semiconductor layer from warping and to provide a nitride-based compound semiconductor substrate suitable for manufacturing a semiconductor device.

### Means for Solving the Problems

In order to solve the above mentioned problems, the invention described in claim 1 is a method of manufacturing a nitride-based compound semiconductor substrate which uses hydride vapor phase epitaxy (HVPE) to react chloride gas generated from a group-III metal and HCl with NH₃ to epitaxially grow a nitride-based compound semiconductor on a substrate, the method comprising:
a first step of forming a low-temperature protecting layer on a rare earth perovskite substrate at a first growth temperature; and
a second step of forming a thick film layer of the nitride-based compound semiconductor on the low-temperature protecting layer at a second growth temperature which is higher than the first growth temperature, wherein
in the first step, supply amounts of HCl and NH₃ are adjusted so that a supply ratio III/V of HCl to NH₃ ranges in 0.016 to 0.13, and the low-temperature protecting layer is formed to have a film thickness of 50 to 90 nm.

The invention described in claim 2 is the method of manufacturing the nitride-based compound semiconductor substrate according to claim 1, wherein in the first step, partial supply pressure of HCl is 3.07×10⁻³ to 8.71×10⁻³ atm, and partial supply pressure of NH₃ is 6.58×10⁻² atm.

The invention described in claim 3 is the method of manufacturing the nitride-based compound semiconductor substrate according to claim 2, wherein in the first step, the partial supply pressure of HCl is 4.37×10⁻³ to 6.55×10⁻³ atm.

The invention described in claim 4 is the method of manufacturing the nitride-based compound semiconductor substrate according to claim 1, wherein in the first step, partial supply pressure of HCl is 2.19×10⁻³, and partial supply pressure of NH₃ is 7.39×10⁻² to 1.23×10⁻¹ atm.

The invention described in claim 5 is the method of manufacturing the nitride-based compound semiconductor substrate according to claim 4, wherein in the first step, the partial supply pressure of NH₃ is 8.76×10⁻² to 1.23×10⁻¹ atm.

The invention described in claim 6 is a nitride-based compound semiconductor free-standing substrate, obtained by separating the thick film layer from the nitride-based compound semiconductor substrate manufactured by the manufacturing method according to any one of claims 1 to 5, wherein
in-plane variations of off-angles with respect to [11-20] and [1-100] directions are respectively not more than 1°.

A description will be given of the development to complete the present invention.

As described above, in the case of manufacturing a GaN free-standing substrate using HVPE, the low-temperature protecting layer composed of GaN is grown before the GaN thick film layer is grown. This low-temperature protecting layer is provided in order to prevent the NGO substrate from being reacted with NH₃ or the like at a growth temperature (800 to 1200° C.) of the GaN thick film layer and changing in nature. However, the growing conditions had not been especially examined. The inventors of the present invention thus examined changes in the warpage of the GaN thick film layer and the in-plane variation of off-angles with respect to a certain direction, according to the growing conditions of the low-temperature protecting layer.

First, based on the conventional growth conditions, we examined the natures of low-temperature protecting layers grown with varying supply amount of any one of HCl as group III material gas and NH₃ as group V material gas. The substrates were NGO substrates; the growth temperature, 600° C.; and the growth time, 7.5 min. To be specific, low-temperature protecting layers were grown with varying supply amount of NH₃ at partial supply pressures of 5.70×10⁻² to 1.54×10⁻¹ atm while the supply amount of HCl was set constant to a partial supply pressure of 2.19×10⁻³ atm. Moreover, low-temperature protecting layers were grown with varying supply amount of HCl at partial supply pressures of 3.07×10⁻³ to 8.71×10⁻³ atm while the supply amount of NH₃ was set constant to a partial supply pressure of 6.58×10⁻² atm.

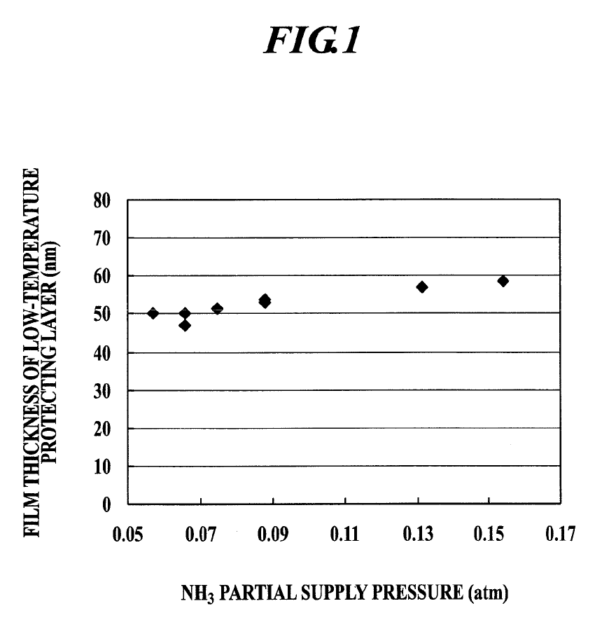

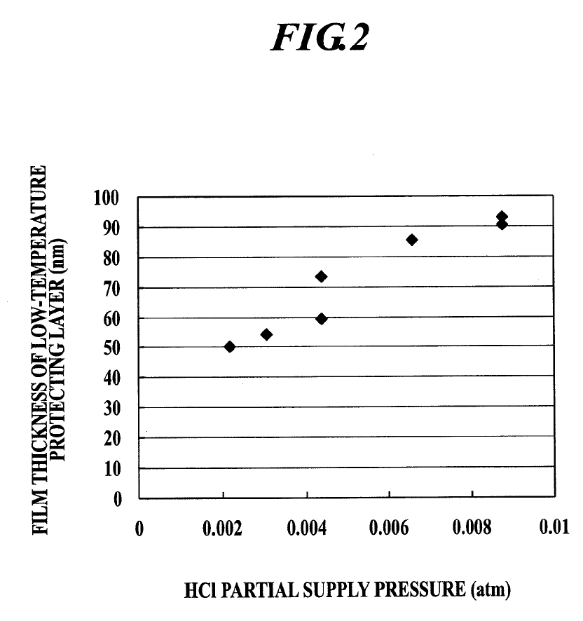

As a result thereof , when the supply amount of raw material gas was varied, the half-value width by X-ray diffraction, film thickness, and surface condition of the low-temperature protecting layer changed. A correlation was observed between the film thickness of the low-temperature protecting layers and the supply amounts of the raw material gases (see FIGS. 1 and 2).

Furthermore, GaN thick film layers were grown on the low-temperature protecting layers grown in such a manner, and the off-angles with respect to the [1-100] and [11-20] directions in the GaN thick film layers were measured. Herein, the measurement was performed at the total of five points including the in-plane central point of each GaN thick film layer and four points locating at the circumferential portion on orthogonal axes passing through the central point. The variation of off-angles at the five measurement points was calculated by (maximum value−minimum value)/2.

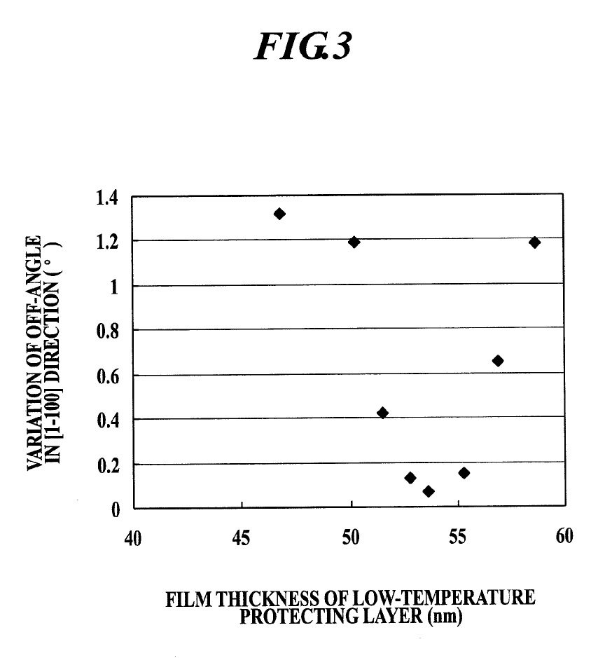

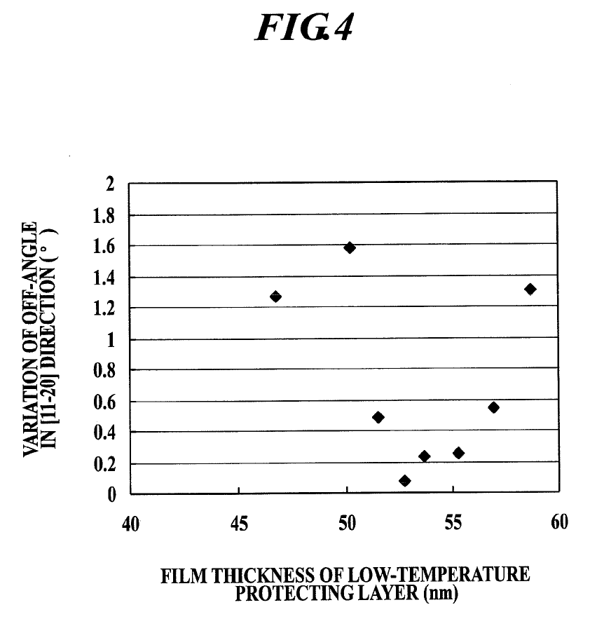

In the low-temperature protecting layers which were grown with varying supply amount of NH₃, there was a tendency of the variation of off-angles to decrease as the film thickness of the low-temperature protecting layer increased to 55 nm, after which the variation of off-angles increased as the film thickness thereof further increased (see FIGS. 3 and 4). Moreover, when the film thickness of the low-temperature protecting layer was 50 to 58 nm, the variation of off-angles was not more than 1.0°, which was obviously better than the low-temperature protecting layers grown under the conventional growth conditions (the low-temperature protecting layers having film thicknesses of a little less than 50 nm).

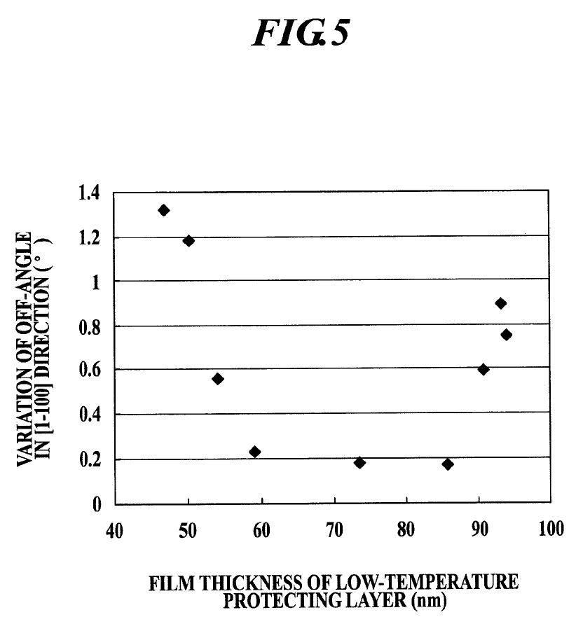

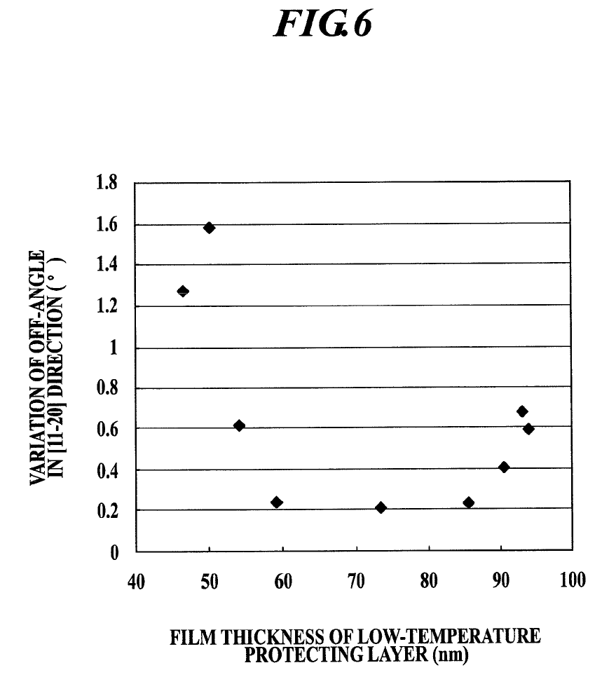

On the other hand, in the low-temperature protecting layers which were grown with varying supply amount of HCl, there was a tendency of the variation of off-angles to decrease as the film thickness of the low-temperature protecting layer increased to 90 nm, after which the variation of off-angles increased as the film thickness thereof further increased (see FIGS. 5 and 6). Moreover, when the film thickness of the low-temperature protecting layer was 50 to 95 nm, the variation of off-angles was not more than 1.0°, which was obviously better than the low-temperature protecting layers grown under the conventional growth conditions.

This revealed that the variation of off-angles of the GaN thick film layer grown on the low-temperature protecting layer could be reduced by growing the low-temperature protecting layer to a predetermined range of film thickness. Moreover, the ranges of film thickness of the low-temperature protecting layers on which the formed GaN thick film layers had small variations of off-angles were different between the case where the low-temperature protecting layers were thickened by increasing the supply amount of NH₃ and the case where the low-temperature protecting layers were thickened by increasing the supply amount of HCl. We therefore arrived at that if the supply amount of NH₃ was excessively increased, NH₃ adversely affected the NGO substrate during growth of the low-temperature protecting layer. This could affect the natures of the low-temperature protecting layer and then variation of off-angles in the GaN thick film layers.

Consequently, we completed the present invention specifying the range of film thickness of the low-temperature protecting layer and the supply amounts of raw material gases (a supply ratio of NH₃ to HCl) which can reduce the variation of off-angles in the GaN thick film layer.

### Effect of the Invention

According to the present invention, it is possible to reproducibly grow a thick film layer of a nitride-based compound semiconductor which is less warped and includes smaller in-plane variation of off-angles and therefore provide a nitride-based compound semiconductor free-standing substrate suitable for manufacturing a semiconductor device.

### BRIEF DESCRIPTION OF DRAWINGS

[FIG. 1] This is a diagram showing a relation between the supply amount of NH₃ at growing a low-temperature protecting layer and film thickness of the low-temperature protecting layer.

[FIG. 2] This is a diagram showing a relation between the supply amount of HCl at growing a low-temperature protecting layer and film thickness of the low-temperature protecting layer.

[FIG. 3] This is a diagram showing a relation between the film thickness of the low-temperature protecting layer and variation of off-angles with respect to the [1-100] direction of the GaN thick film layer in the case of changing the supply amount of NH₃.

[FIG. 4] This is a diagram showing a relation between the film thickness of the low-temperature protecting layer and variation of off-angles with respect to the [11-20] direction of the GaN thick film layer in the case of changing the supply amount of NH₃.

[FIG. 5] This is a diagram showing a relation between the film thickness of the low-temperature protecting layer and variation of off-angles with respect to the [1-100] direction of the GaN thick film layer in the case of changing the supply amount of HCl.

[FIG. 6] This is a diagram showing a relation between the film thickness of the low-temperature protecting layer and variation of off-angles with respect to the [11-20] direction of the GaN thick film layer in the case of changing the supply amount of HCl.

### MODES FOR CARRYING OUT THE INVENTION

Hereinafter, a description is given of an embodiment of the present invention in detail.

In this embodiment, the description is given of a method of manufacturing a GaN substrate by epitaxially growing GaN as a GaN-based semiconductor on an NGO substrate composed of a rare earth perovskite. In HVPE process, chloride gas (GaCl) generated by HCl and Ga as a group-III metal is reacted with NH₃ for epitaxial growth of a GaN layer on a substrate.

First, the NGO substrate is placed in an HVPE apparatus, and the temperature of the substrate is increased to a first growth temperature (400 to 800° C.). GaCl as a group-III raw material generated from Ga metal and HCl, and NH₃ as a group-V raw material are then supplied onto the NGO substrate to form a low-temperature protecting layer made of GaN to a film thickness of 40 to 100 nm.

At this time, in order to prevent the NGO substrate from changing in nature due to NH₃, the supply amounts of the raw material gases are adjusted so that the ratio III/V in supply amount of HCl to NH₃ is 0.16 to 0.13. Desirably, NH₃ is supplied at a partial supply pressure of not more than 1.23×10⁻¹ atm.

Subsequently, the temperature of the substrate is increased to a second growth temperature (950 to 1050° C.). The raw material gas is supplied onto the low-temperature protecting layer to form a GaN thick film layer. The conditions (growing temperature, growing time, and supply amounts of raw material gasses) for growing the GaN thick film layer are not particularly limited and can be general conditions for growing GaN, for example.

As described above, the GaN substrate with the low-temperature protecting layer and GaN thick film layer formed on the NGO substrate is formed. The GaN thick film layer of the GaN substrate is not warped, and the in-plane variations of off-angles with respect to the [1-100] and [11-20] directions are not more than 1°. Moreover, after the obtained GaN substrate is cooled down to room temperature, the NGO substrate is removed by a suitable method, and the product is polished to obtain a GaN free-standing substrate. In the thus-obtained GaN free-standing substrate, the in-plane variations of off-angles with respect to the [1-100] and [11-20] directions are also not more than 1°. Accordingly, by using the thus-obtained GaN free-standing substrate as a substrate at manufacturing a semiconductor device, the semiconductor device can be configured to have desired characteristics.

### EXAMPLE 1

In Example 1, the low-temperature protecting layers composed of GaN were grown by supplying raw material gas at a supply ratio III/V of HCl to NH₃ of 0.046 to 0.13 (the partial supply pressures of HCl and NH₃ were 3.07×10⁻³ to 8.71×10⁻¹ atm and 6.58×10⁻² atm, respectively). At this time, the growth temperature was set to 600° C., and the growth time was set constant to 7.5 min. The film thickness of the formed low-temperature protecting layers increased to between 50 to 90 nm with an increase in the supply amount (partial supply pressure) of HCl.

Subsequently, raw material gas was supplied onto each of the low-temperature protecting layers at a partial supply pressure of HCl of 1.06×10⁻² atm and a partial supply pressure of NH₃ of 5.00×10⁻² atm to form a GaN thick film layer with a thickness of 2500 μm. At this time, the growth temperature was set to 1000° C., and the growth time was set constant to 8 hours.

The thus-obtained GaN thick film layers were visually observed in terms of warpage. The GaN thick film layers of Example 1 were obviously less warped than those of Comparative Examples later described.

Moreover, the off-angles with respect to the [1-100] and [11-20] directions were measured at five points in a plane in each GaN thick film layer. The in-plane variations of the measured off-angles in each GaN thick film layer were not more than 1°, which were good results. When the partial supply pressure of HCl was set to between 4.37×10⁻³ and 6.55×10⁻³ atm, the low-temperature protecting layers have film thicknesses of 60 to 90 nm. The in-plane variations of off-angles of each GaN thick film layer were not more than 0.3°.

Furthermore, the NGO substrates were removed from the GaN substrate by a suitable method to separate the GaN thick film layers. The GaN thick film crystals were polished to produce GaN free-standing substrates. In the GaN free-standing substrates, the variations of off-angles with respect to the [1-100] and [11-20] directions were not more than 0.3°.

### EXAMPLE 2

In Example 2, the low-temperature protecting layers composed of GaN were grown by supplying raw material gas at a supply ratio III/V of HCl to NH₃ of 0.017 to 0.029 (the partial supply pressures of NH₃ and HCl were 7.39×10⁻² to 1.23×10⁻³ atm and 2.19×10⁻³ atm, respectively). At this time, the growth temperature was set to 600° C., and the growth time was set constant to 7.5 min. The film thickness of the formed low-temperature protecting layers increased to between 50 and 58 nm with an increase in the supply amount (partial supply pressure) of NH₃. On each low-temperature protecting layer, a GaN thick film layer was grown in a similar manner to Example 1.

The thus-obtained GaN thick film layers were visually observed in terms of warpage. The GaN thick film layers of Example 2 were obviously less warped than those of Comparative Examples later described.

Moreover, the off-angles with respect to the [1-100] and [11-20] directions were measured at five points in a plane in each GaN thick film layer. The in-plane variations of the measured off-angles in each GaN thick film layer were not more than 1°, which were good results. Especially when the partial supply pressure of NH₃ was set to between 8.58×10⁻² and 1.05×10⁻¹ atm, the low-temperature protecting layers have film thicknesses of 52 to 53 nm, and the in-plane variations of off-angles of each GaN thick film layer were not more than 0.3°.

Furthermore, the NGO substrates were removed from the GaN substrate by a suitable method to separate the GaN thick film layers. The GaN thick film crystals were polished to produce GaN free-standing substrates. In the GaN free-standing substrates, the variations of off-angles with respect to the [1-100] and [11-20] directions were not more than 0.3°.

### COMPARATIVE EXAMPLE 1

In Comparative Example 1, the low-temperature protecting layer composed of GaN was grown by supplying raw material gas at a supply ratio III/V of HCl to NH₃ of 0.033 (the partial supply pressures of HCl and NH₃ were 2.19×10⁻² and 6.58×10⁻² atm, respectively). At this time, the growth temperature was set to 600° C., and the growth time was set constant to 7.5 min. The film thickness of the formed low-temperature protecting layer was 47 nm. On this low-temperature protecting layer, a GaN thick film layer was grown in a similar manner to Examples 1 and 2.

The thus-obtained GaN thick film layer was visually observed in terms of warpage, and distinct warpage was confirmed.

Moreover, the off-angles with respect to the [1-100] and [11-20] directions were measured at five points in a plane of the GaN thick film layer. The in-plane variations of the measured off-angles with respect to the [1-100] and [11-20] directions were 1.32° and 1.58°, respectively.

Furthermore, the NGO substrate was removed from the GaN substrate by a suitable method to separate the GaN thick film layer. The GaN thick film crystal was polished to produce GaN free-standing substrates. In each GaN free-standing substrate, the variations of off-angles with respect to the [1-100] and [11-20] directions were more than 1°.

### COMPARATIVE EXAMPLE 2

In Comparative Example 2, the low-temperature protecting layers composed of GaN were grown by supplying raw material gas at a supply ratio III/V of HCl and NH₃ of 0.014 (the partial supply pressures of HCl and NH₃ were 2.19×10⁻³ and 1.54×10⁻¹ atm, respectively). At this time, the growth temperature was set to 600° C., and the growth time was set constant to 7.5 min. The film thickness of the formed low-temperature protecting layer was 58.7 nm. On the low-temperature protecting layer, a GaN thick film layer was grown in a similar manner to Examples 1 and 2.

The thus-obtained GaN thick film layer was visually observed in terms of warpage, and obvious warpage was confirmed.

Moreover, the off-angles with respect to the [1-100] and [11-20] directions were measured at five points in a plane in each GaN thick film layer. The in-plane variations of the measured off-angles in the GaN thick film layer with respect to the [1-100] and [11-20] directions were 1.18° and 1.31°, respectively.

Furthermore, the NGO substrate was removed from the GaN substrate by a suitable method to separate the GaN thick film layer. The GaN thick film crystal was polished to produce a GaN free-standing substrate. In the GaN free-standing substrate, the variations of off-angles with respect to the [1-100] and [11-20] directions were more than 1°.

As described above, according to the embodiment, the supply amount of raw material gas, which is one of the growing conditions of the low-temperature protecting layer, is changed to change the nature (film thickness) of the low-temperature protecting layer. This makes it possible to reproducibly grow a thick film layer of a nitride-based compound semiconductor which includes less warpage and smaller in-plane variation of off-angles.

Moreover, the GaN thick film layer is separated from the GaN substrate obtained in the embodiment to be polished into a GaN free-standing substrate. The produced GaN free-standing substrate is therefore suitable for manufacturing a semiconductor device.

Hereinabove, the present invention made by the inventors is specifically described based on the embodiment. However, the present invention is not limited to the above embodiment and can be changed without departing from the scope of the same.

The above embodiment describes the manufacture of the GaN free-standing substrate. However, the present invention can be applied to the case of growing a nitride-based compound semiconductor layer on a substrate using HVPE to manufacture a nitride-based compound semiconductor substrate. Herein, the nitride-based compound semiconductor is one of compound semiconductors expressed by InₓGa_{y}Al_{1-x-y}N (0≦x+y≦1, 0≦x≦1, and 0≦y≦1), and examples thereof are GaN, InGaN, AlGaN, InGaAlN, and the like.

The embodiment disclosed herein should be thought to be just an example in all respects and be not restrictive. The scope of the present invention is indicated not by the above explanation but by the claims and is intended to contain the claims, equivalents thereof, and modifications within the scope.

1-6. (canceled)

7. A method of manufacturing a nitride-based compound semiconductor substrate which uses hydride vapor phase epitaxy (HVPE) to react chloride gas generated from a group-III metal and HCl with NH₃ to epitaxially grow a nitride-based compound semiconductor on a substrate, the method comprising:
a first step of forming a low-temperature protecting layer on a rare earth perovskite substrate at a first growth temperature; and
a second step of forming a thick film layer of the nitride-based compound semiconductor on the low-temperature protecting layer at a second growth temperature which is higher than the first growth temperature, wherein
in the first step, supply amounts of HCl and NH₃ are adjusted so that a supply ratio III/V of HCl to NH₃ ranges in 0.016 to 0.13, and the low-temperature protecting layer is formed to have a film thickness of 50 to 90 nm, and wherein
in the first step, partial supply pressure of HCl is 3.07×10⁻³ to 8.71×10⁻³ atm, and partial supply pressure of NH₃ is 6.58×10⁻² atm.

8. The method of manufacturing the nitride-based compound semiconductor substrate according to claim 7, wherein in the first step, the partial supply pressure of HCl is 4.37×10⁻³ to 6.55×10⁻³ atm.

9. A method of manufacturing a nitride-based compound semiconductor substrate which uses hydride vapor phase epitaxy (HVPE) to react chloride gas generated from a group-III metal and HCl with NH₃ to epitaxially grow a nitride-based compound semiconductor on a substrate, the method comprising:
a first step of forming a low-temperature protecting layer on a rare earth perovskite substrate at a first growth temperature; and
a second step of forming a thick film layer of the nitride-based compound semiconductor on the low-temperature protecting layer at a second growth temperature which is higher than the first growth temperature, wherein
in the first step, supply amounts of HCl and NH₃ are adjusted so that a supply ratio III/V of HCl to NH₃ ranges in 0.016 to 0.13, and the low-temperature protecting layer is formed to have a film thickness of 50 to 90 nm, and wherein in the first step, partial supply pressure of HCl is 2.19×10⁻³, and partial supply pressure of NH₃ is 7.39×10⁻² to 1.23×10⁻¹ atm.

10. The method of manufacturing the nitride-based compound semiconductor substrate according to claim 9, wherein in the first step, the partial supply pressure of NH₃ is 8.76×10⁻² to 1.23×10⁻¹ atm.

11. A nitride-based compound semiconductor free-standing substrate, obtained by separating the thick film layer from the nitride-based compound semiconductor substrate manufactured by the manufacturing method according to claim 7, wherein
in-plane variations of off-angles with respect to [11-20] and [1-100] directions are respectively not more than 1°.

12. A nitride-based compound semiconductor free-standing substrate, obtained by separating the thick film layer from the nitride-based compound semiconductor substrate manufactured by the manufacturing method according to claim 9, wherein
in-plane variations of off-angles with respect to [11-20] and [1-100] directions are respectively not more than 1°.
